(19) United States
(12) Patent Application Publication
(10) Pub. No.: US 2008/0237824 A1
(43) Pub. Date: Oct. 2, 2008

(54) Stacked electronic component package having single-sided film spacer

(75) Inventors: Roger D. St. Amand, Tempe, AZ (US); ChangSuk Han, Sungnam (KR); YounSang Kim, Sungnam (KR); KyungRok Park, Kwangju (KR)

Correspondence Address: GUNNISON MCKAY & HODGSON, LLP;GARDEN WEST OFFICE PLAZA, SUITE 220, 1900 GARDEN ROAD, MONTEREY, CA, 93940, US

(73) Assignee: Amkor Technology, Inc.

(21) Appl. No.: 11/356,919

(22) Filed: Feb. 17, 2006

(51) Int. Cl. H01L 23/02

(52) U.S. Cl. 257/686

(57) ABSTRACT

A method of fabricating a stacked electronic component package includes placing a single-sided film spacer on an upper surface of a lower electronic component inward of bond pad with a pickup tool. After being adhered to the upper surface of the lower electronic component, the pickup tool is retracted from the single-sided film spacer. An upper surface of a film, e.g., an organic film, of the single-sided film spacer is nonadhesive. Accordingly, the single-sided film spacer does not stick to the pickup tool during retraction of the pickup tool from the single-sided film spacer.

This application is related to St. Amand et al., commonly assigned and co-filed U.S. patent application Ser. No. [ATTORNEY DOCKET NUMBER G0090], entitled “STACKED ELECTRONIC COMPONENT PACKAGE HAVING FILM-ON-WIRE SPACER”, which is herein incorporated by reference in its entirety.

### BACKGROUND OF THE INVENTION

1. Field of the Invention

The present invention relates generally to the packaging of electronic components. More particularly, the present invention relates to a stacked electronic component package and method for fabricating the same.

2. Description of the Related Art

To reduce the size of electronic component packages, electronic components such as semiconductor dies were stacked one upon another within a stacked electronic component package. To space the upper electronic component above the lower bond wires connected to the bond pads of the lower electronic component, a spacer was used.

The spacer was mounted to the upper surface of the lower electronic component inward of the bond pads on the upper surface of the lower electronic component. The lower bond wires were connected to the bond pads on the upper surface of the lower electronic component. The lower surface of the upper electronic component was mounted to the spacer, which spaced the lower surface of the upper electronic component away from the upper surface of the lower electronic component and the lower bond wires.

A spacer made of silicon, i.e., a silicon spacer, was used. As a silicon spacer is nonadhesive, use of the silicon spacer required an upper and lower adhesive. The lower adhesive mounted the lower surface of the silicon spacer to the upper surface of the lower electronic component inward of the bond pads of the lower electronic component. As the upper surface of the silicon spacer did not have adhesive applied thereto during mounting of the silicon spacer to the lower electronic component, the silicon spacer did not adhere to the vacuum head of the pickup tool that placed the silicon spacer on the lower electronic component.

The upper adhesive, e.g., a film adhesive, was applied to the entire lower surface of the upper electronic component. The upper electronic component having the upper adhesive applied to the entire lower surface of the upper electronic component was then mounted to the silicon spacer.

An alternative to the silicon spacer was a double-sided film spacer. A double-sided film spacer had adhesive on both the upper and lower surfaces of the double-sided film spacer. This allowed the double-sided film spacer to be mounted directly to the upper surface of the lower electronic component and the upper electronic component to be directly mounted to the double-sided film spacer with or without the application of additional adhesives. This simplified manufacturing resulting in a lower manufacturing cost of the stacked electronic component package. Further, a double-sided film spacer was less expensive than a silicon spacer again resulting in a lower manufacturing cost of the stacked electronic component package.

One problem associated with the double-sided film spacer was that the adhesive upper surface of the double-sided film spacer adhered to the vacuum head of the pickup tool. Thus, during retraction of the vacuum head, the double-sided film spacer was pulled from the upper surface of the lower electronic component resulting in the formation of interfacial voids between the lower surface of the double-sided film spacer and the upper surface of the lower electronic component. The interfacial voids sometimes caused delamination of the double-sided film spacer from the lower electronic component thus reducing the yield of the stacked electronic component package and in some cases adversely impacting the package reliability.

### SUMMARY OF THE INVENTION

In accordance with one embodiment, a method of fabricating a stacked electronic component package includes placing a single-sided film spacer on an upper surface of a lower electronic component inward of bond pad with a pickup tool. After being adhered to the upper surface of the lower electronic component, the pickup tool is retracted from the single-sided film spacer.

An upper surface of a film, e.g., an organic film, of the single-sided film spacer is nonadhesive. Accordingly, the single-sided film spacer does not stick to the pickup tool during retraction of the pickup tool from the single-sided film spacer. Thus, voiding between the single-sided film spacer and the lower electronic component and the associated loss of yield of fabrication of the stacked electronic component package is minimized. Further, the single-sided film spacer is relatively inexpensive compared to a silicon spacer and thus the stacked electronic component package is fabricated with a minimal cost.

These and other features of the present invention will be more readily apparent from the detailed description set forth below taken in conjunction with the accompanying drawings.

### BRIEF DESCRIPTION OF THE DRAWINGS

FIG. 1 is a cross-sectional view of a stacked electronic component package in accordance with one embodiment of the present invention;

FIG. 2A is an enlarged cross-sectional view of the region II of the stacked electronic component package of FIG. 1 in accordance with one embodiment of the present invention;

FIGS. 2B, 2C are enlarged cross-sectional views of regions of stacked electronic component packages in accordance with other embodiments of the present invention;

FIGS. 3A, 3B are cross-sectional and perspective views, respectively, of assemblies during the fabrication of a plurality of single-sided film spacers in accordance with various embodiments of the present invention;

FIG. 4 is a cross-sectional view of the stacked electronic component package of FIG. 1 during fabrication in accordance with one embodiment of the present invention; and

FIG. 5 is a cross-sectional view of a stacked electronic component package in accordance with another embodiment of the present invention.

In the following description, the same or similar elements are labeled with the same or similar reference numbers.

### DETAILED DESCRIPTION

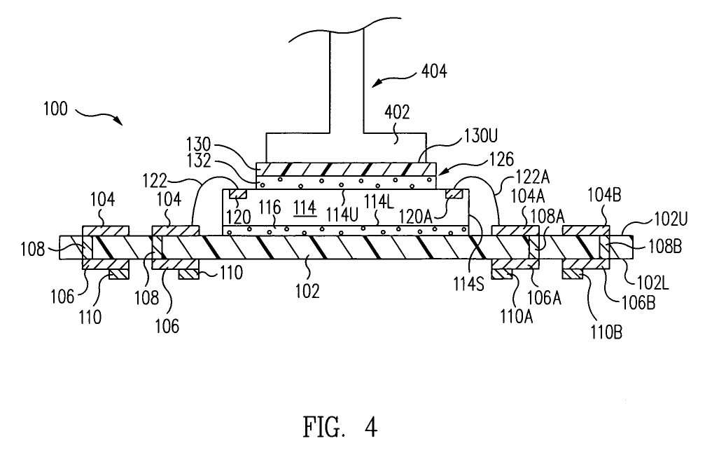

In accordance with one embodiment, referring to FIG. 4, a method of fabricating a stacked electronic component package 100 includes placing a single-sided film spacer 126 on an upper surface 114U of a lower electronic component 114 inward of bond pads 120 with a pickup tool 404. After being adhered to (pressed on) upper surface 114U of lower electronic component 114, pickup tool 404 is retracted from single-sided film spacer 126.

An upper surface 130U of a film 130, e.g., an organic film, of single-sided film spacer 126 is not adhesive. Accordingly, single-sided film spacer 126 does not stick to pickup tool 404 during retraction of pickup tool 404 from single-sided film spacer 126. Thus, voiding between single-sided film spacer 126 and lower electronic component 114 and the associated loss of yield of fabrication of stacked electronic component package 100 is minimized. Further, single-sided film spacer 126 is relatively inexpensive compared to a silicon spacer and thus stacked electronic component package 100 is fabricated with a minimal cost.

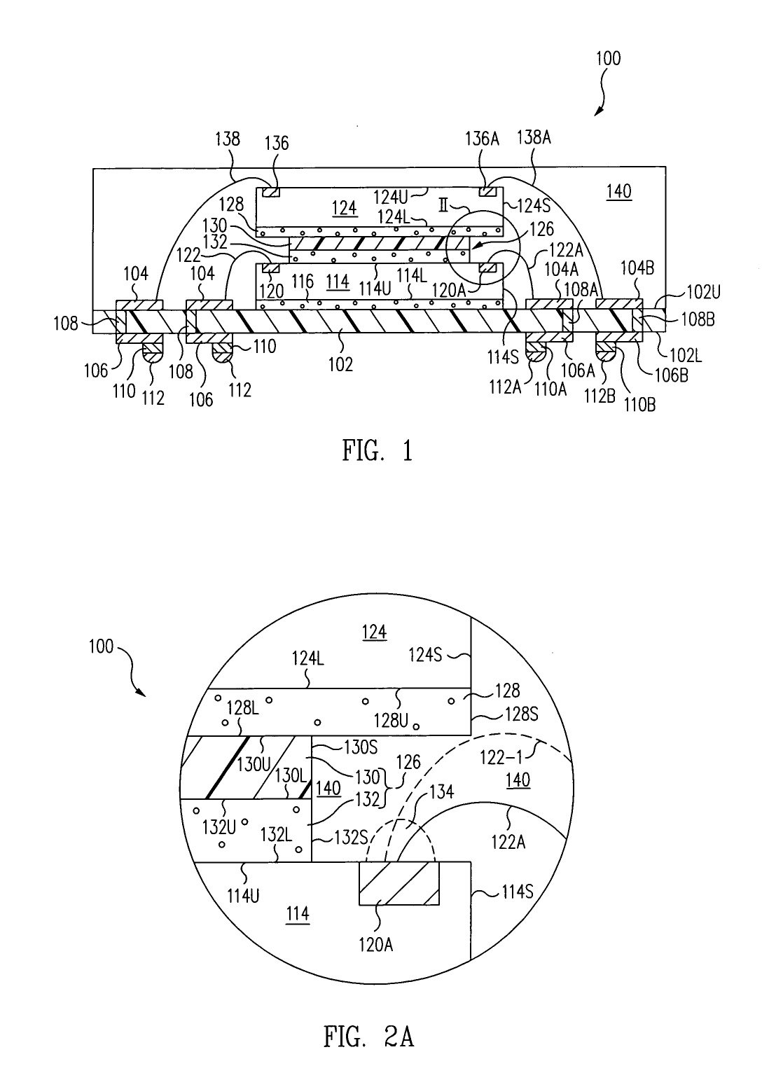

More particularly, FIG. 1 is a cross-sectional view of a stacked electronic component package 100 in accordance with one embodiment of the present invention. Stacked electronic component package 100 includes a substrate 102, e.g., formed of metal, with ceramic, pre-molded plastic or laminate material, although substrate 102 may be formed of other materials in other embodiments. Substrate 102 includes an upper, e.g., first, surface 102U and a lower, e.g., second, surface 102L, opposite upper surface 102U.

Formed on upper surface 102U of substrate 102 are a plurality of electrically conductive upper, e.g., first, traces 104, which include a first upper trace 104A and a second upper trace 104B. Formed on lower surface 102L of substrate 102 are a plurality of electrically conductive lower, e.g., second, traces 106, which include a first lower trace 106A and a second lower trace 106B. Extending through substrate 102 from lower surface 102L to upper surface 102U are a plurality of electrically conductive vias 108, which include a first via 108A and a second via 108B. Lower traces 106 are electrically connected to upper traces 104 by vias 108. To illustrate, lower traces 106A, 106B are electrically connected to upper traces 104A, 104B by vias 108A, 108B, respectively. Upper and lower surfaces 102U, 102L of substrate 102 may include an outermost insulative cover coat, e.g., an epoxy based resin, through which electrically conductive bond fingers, e.g., the end portions, of upper traces 104 and pads 110 are exposed.

Formed on lower traces 106 are electrically conductive pads 110, which include a first pad 110A and a second pad 110B. Formed on pads 110 are electrically conductive interconnection balls 112, e.g., solder. To illustrate, pads 110A, 110B are formed on lower traces 106A, 106B, respectively. First and second interconnection balls 112A, 112B of the plurality of interconnection balls 112 are formed on pads 110A, 110B, respectively. Interconnection balls 112 are used to connect stacked electronic component package 100 to a larger substrate such as a printed circuit mother board or another electronic component package.

Although a particular electrically conductive pathway between upper traces 104 and interconnection balls 112 is described above, other electrically conductive pathways can be formed. For example, contact metallizations can be formed between the various electrical conductors. Alternatively, pads 110 are not formed and interconnection balls 112 are formed directly on lower traces 106.

Further, instead of straight though vias 108, in one embodiment, substrate 102 is a multilayer laminate substrate and a plurality of vias and/or internal traces form the electrical interconnection between traces 104 and 106.

In yet another embodiment, interconnection balls 112 are distributed in an array format to form a ball grid array (BGA) type package. Alternatively, interconnection balls 112 are not formed, e.g., to form a metal land grid array (LGA) type package. In yet another alternative, pads 110/interconnection balls 112 are not formed, e.g., to form a leadless chip carrier (LCC) type package. In another embodiment, stacked electronic component package 100 is inserted into a socket that is pre-mounted on the larger substrate, e.g., on the printed circuit mother board. BGA, LGA and LCC type modules are well known to those of skill in the art.

In another embodiment, a flex connector, sometimes called an edge connector or flex strip, is electrically connected to lower traces 106, e.g., for applications where stacked electronic component package 100 is remote from the larger substrate. Other electrically conductive pathway modifications will be obvious to those of skill in the art.

Referring still to FIG. 1, mounted, sometimes called die attached, to upper surface 102U of substrate 102 is a lower, e.g., first, electronic component 114. More particularly, a lower, e.g., first, surface 114L of lower electronic component 114 is mounted to upper surface 102U, for example, with an adhesive 116, sometimes called a die attach adhesive.

Lower electronic component 114 further includes an upper, e.g., second, surface 114U. Bond pads 120 of lower electronic component 114 are formed on upper surface 114U adjacent sides 114S of lower electronic component 114. In this embodiment, upper surface 102U, lower surface 114L, and upper surface 114U are parallel to one another. Although various structures may be described as being parallel or perpendicular, it is understood that the structures may not be exactly parallel or perpendicular but only substantially parallel or perpendicular to within accepted manufacturing tolerances.

In accordance with this embodiment, lower electronic component 114 is a semiconductor die, sometimes called a lower semiconductor die, integrated circuit chip or an active component. However, in other embodiments, lower electronic component 114 is another type of electronic component such as a passive component, e.g., a resistor, capacitor or inductor.

Upper traces 104 are electrically connected to bond pads 120 by lower bond wires 122. To illustrate, a first bond pad 120A of the plurality of bond pads 120 is electrically connected to upper trace 104A by a first lower bond wire 122A of the plurality of lower bond wires 122.

An upper, e.g., second, electronic component 124 is mounted to lower electronic component 114. More particularly, a lower, e.g., first, surface 124L of upper electronic component 124 is mounted to upper surface 114U of lower electronic component 114 with a single-sided film spacer 126 and an upper electronic component adhesive 128.

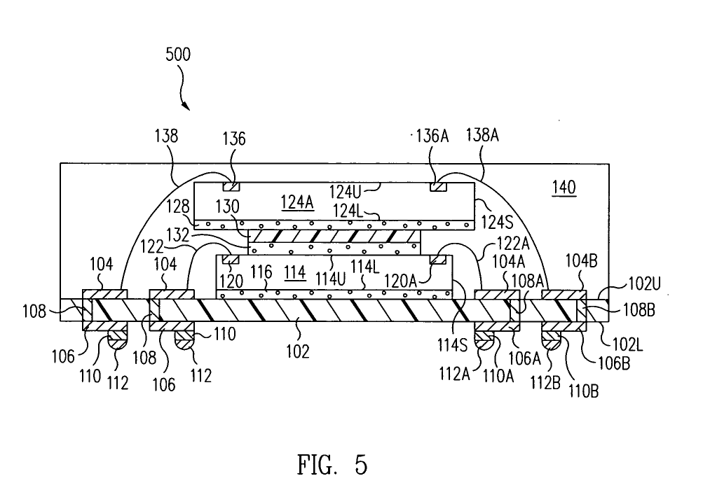

In accordance with this embodiment, lower surface 124L of upper electronic component 124 corresponds to upper surface 114U of lower electronic component 114. Stated another way, lower surface 124L of upper electronic component 124 has the same shape, e.g., a rectangular shape having the same length and width, as upper surface 114U of lower electronic component 114 such that the total surface areas of lower surface 124L and upper surface 114U are equal. However, in other embodiments, the total area of lower surface 124L of upper electronic component 124 is greater than or less than, i.e., different than, the total area of upper surface 114U of lower electronic component 114. Such an example is discussed below in reference to FIG. 5.

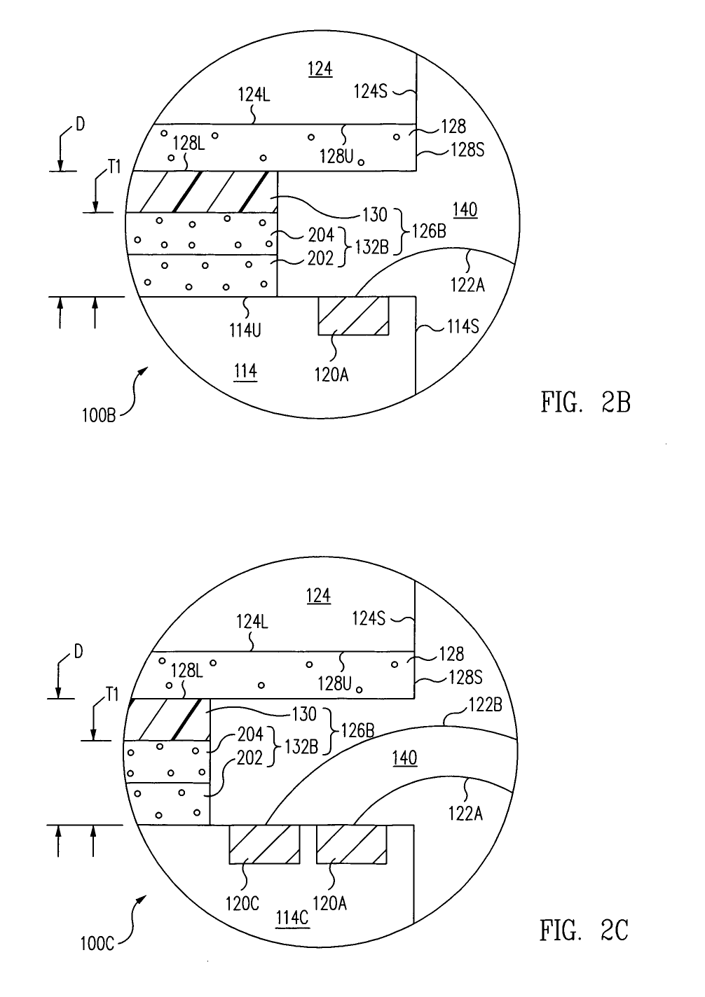

FIG. 2A is an enlarged cross-sectional view of the region II of stacked electronic component package 100 of FIG. 1 in accordance with one embodiment of the present invention. Referring now to FIGS. 1 and 2A together, single-sided film spacer 126 includes a film 130 and a lower film adhesive 132. Film 130, sometimes called a spacer, is a nonconductive, nonadhesive, flexible film. In one embodiment, film 130 is formed of polyimide, e.g., is a polyimide film. In accordance with this embodiment, film 130 is an organic film. Film 130 includes a lower, e.g., first, surface 130L, an upper, e.g., second, surface 130U, and sides 130S extending between upper surface 130U and lower surface 130L.

Lower surface 130L of film 130 is directly mounted to upper surface 114U of lower electronic component 114 with lower film adhesive 132. More particularly, a lower, e.g., first, surface 132L of lower film adhesive 132 is mounted to upper surface 114U of lower electronic component 114. Generally, lower film adhesive 132, sometimes called a spacer film adhesive, is adhesive such that lower surface 132L of lower film adhesive 132 directly adheres to upper surface 114U of lower electronic component 114.

Similarly, an upper, e.g., second, surface 132U of lower film adhesive 132 is mounted to lower surface 130L of film 130. Again, lower film adhesive 132 is adhesive such that upper surface 132U of lower film adhesive 132 directly adheres to lower surface 130L of film 130.

In accordance with this embodiment, lower film adhesive 132 is an adhesive film, sometimes called a film adhesive. Generally, lower film adhesive 132 is a preformed film of adhesive, e.g., a layer or sheet of adhesive. As such, lower film adhesive 132 has sides 132S which are substantially vertical and coincident with sides 130S of film 130. In one embodiment, lower film adhesive 132 is a preformed layer of epoxy. In contrast, a conventional paste adhesive would be applied as a viscous paste and thus would have curved protruding sides instead of substantially vertical sides 132S of lower film adhesive 132. However, in one embodiment, lower film adhesive 132 is a film adhesive that flows during the curing process, and thus has curved protruding sides.

Upper film adhesive 128, sometimes called a second electronic component film adhesive, is mounted to and covers the entire lower surface 124L of upper electronic component 124. Generally, upper film adhesive 128 is adhesive, i.e., sticky, such that an upper, e.g., first, surface 128U of upper film adhesive 128 directly adheres to lower surface 124L of upper electronic component 124.

In accordance with this embodiment, upper film adhesive 128 is an adhesive film, sometimes called a film adhesive. Generally, upper film adhesive 128 is a preformed film of adhesive, e.g., a layer or sheet of adhesive. As such, upper film adhesive 128 has sides 128S which are substantially vertical and coincident with sides 124S of upper electronic component 124. In one embodiment, upper film adhesive 128 is a preformed layer of epoxy.

In accordance with this embodiment, upper film adhesive 128 is nonconductive, i.e., a dielectric. Upper film adhesive 128 is located vertically above bond pads 120. More particularly, upper film adhesive 128 is located vertically between bond pads 120 and lower surface 124L of upper electronic component 124.

Accordingly, upper film adhesive 128 protects lower surface 124L of upper electronic component 124 from lower bond wires 122 and vice versa. More particularly, upper film adhesive 128 prevents lower bond wires 122 from directly contacting and shorting to lower surface 124L.

In accordance with one embodiment, single-sided film spacer 126 spaces upper film adhesive 128 a distance above bond pads 120 sufficient to prevent lower bond wires 122 from contacting upper film adhesive 128. However, as indicated by the phantom bond wire 122-1 in FIG. 2A, in one embodiment, lower bond wires 122 contact upper film adhesive 128.

In accordance with another embodiment, lower bond wires 122 are bonded to bond pads 120 using a reverse bonding technique, sometimes called stand-off stitch bonding (SSB) to minimize the loop height of lower bond wires 122. By minimizing the loop height of lower bond wires 122, the thickness of single-sided film spacer 126 required to avoid contact between lower bond wires 122 and upper film adhesive 128 is also minimized.

As is well known to those of skill in the art, in reverse bonding, a ball 134 (indicated as a dashed line in FIG. 2A) is initially formed on bond pad 120A and the wire is broken at the top of ball 134. A similar ball is formed on the respective upper trace 104, sometimes called a bond finger, and lower bond wire 122A is then extended back to ball 134. Lower bond wire 122A is bonded to ball 134 and thus to bond pads 120A using a standard stitch bond.

Referring again to FIG. 1, upper electronic component 124 further includes an upper, e.g., second, surface 124U. Bond pads 136 are formed on upper surface 124U of upper electronic component 124. In accordance with this embodiment, upper electronic component 124 is a semiconductor die, sometimes called an upper semiconductor die, integrated circuit chip or an active component. However, in other embodiments, upper electronic component 124 is another type of electronic component such as a passive component, e.g., a resistor, capacitor or inductor.

Upper traces 104 are electrically connected to bond pads 136 by upper bond wires 138. To illustrate, a first bond pad 136A of the plurality of bond pads 136 is electrically connected to upper trace 104B by a first upper bond wire 138A of the plurality of upper bond wires 138.

A package body 140, e.g., a cured liquid encapsulant or mold compound, encloses lower electronic component 114, single-sided film spacer 126, upper film adhesive 128, upper electronic component 124, lower bond wires 122, upper bond wires 138, and all or part of the exposed upper surface 102U of substrate 102. In one embodiment, package body 140 is vertically between and fills the space between bond pads 120 and upper film adhesive 128. In accordance with this embodiment, package body 140 extends inward to single-sided film spacer 126 and between upper film adhesive 128 and upper surface 114U of lower electronic component 114.

FIG. 2B is an enlarged cross-sectional view of a region of a stacked electronic component package 100B in accordance with another embodiment of the present invention. Stacked electronic component package 100B of FIG. 2B is similar to stacked electronic component package 100 of FIG. 2A and only the significant differences between stacked electronic component package 100B and stacked electronic component package 100 are discussed below.

Referring now to FIG. 2B, stacked electronic component package 100B includes a single-sided film spacer 126B. Single-sided film spacer 126B includes a film 130 and a multilayer lower film adhesive 132B. Multilayer lower film adhesive 132B, sometimes called a spacer film adhesive, includes more than one film adhesive and specifically includes a first lower film adhesive 202 and a second lower film adhesive 204.

By using two lower film adhesives 202, 204, the thickness T1 of multilayer lower film adhesive 132B is greater than, e.g., double, the thickness of either lower film adhesive 202 or lower film adhesive 204. Although multilayer lower film adhesive 132B is illustrated and discussed as including two film adhesives, i.e., lower film adhesives 202, 204, it is understood that multilayer lower film adhesive 132B can be fabricated with more than two lower film adhesives depending upon the desired distance D between lower surface 128L of upper film adhesive 128 and upper surface 114U of lower electronic component 114. Additionally, the thickness of each individual film adhesive may be varied to adjust the overall thickness between lower surface 128L of upper film adhesive 128 and upper surface 114U of lower electronic component 114.

To illustrate, in one embodiment, multilayer lower film adhesive 132B is fabricated to include a third lower film adhesive in addition to lower film adhesives 202, 204 to increase distance D between lower surface 128L of upper film adhesive 128 and upper surface 114U of lower electronic component 114 compared to forming multilayer lower film adhesive 132B from only lower film adhesives 202, 204. In this manner, distance D is readily selected by using more or less lower film adhesives to form multilayer lower film adhesive 132B.

FIG. 2C is an enlarged cross-sectional view of a region of a stacked electronic component package 100C in accordance with another embodiment of the present invention. Stacked electronic component package 100C of FIG. 2C is similar to stacked electronic component package 100B of FIG. 2B and only the significant differences between stacked electronic component package 100C and stacked electronic component package 100B are discussed below.

Referring now to FIG. 2C, stacked electronic component package 100C includes a lower electronic component 114C having an inner bond pad 120C inward of bond pad 120A. In accordance with this embodiment, multilayer lower film adhesive 132B uses lower film adhesives 202, 204 to ensure that distance D between lower surface 128L of upper film adhesive 128 and upper surface 114U of lower electronic component 114C is sufficient to prevent a lower bond wire 122B connected to inner bond pad 120C from being pushed down into and shorting against bond wire 122A.

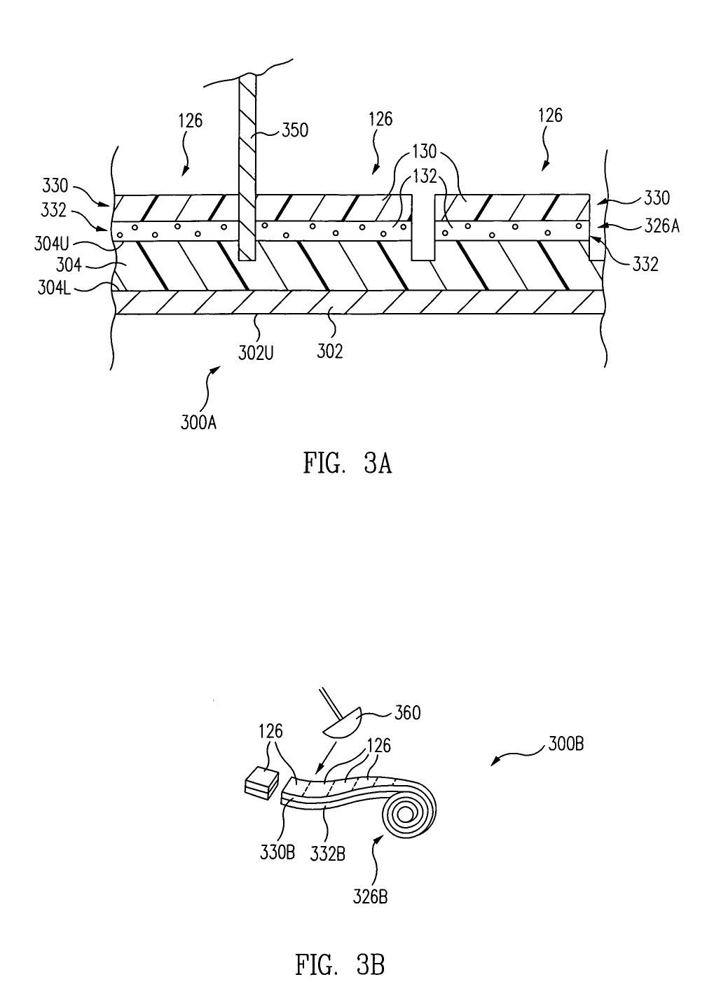

FIG. 3A is a cross-sectional view of an assembly 300A during the fabrication of a plurality of single-sided film spacers 126 in accordance with one embodiment of the present invention. Referring now to FIG. 3A, assembly 300A includes a rigid support 302. A lower, e.g., first, surface 304L of a single-sided film spacer singulation tape 304, sometimes called a wafer sticky tape, is mounted to an upper, e.g., first surface 302U of support 302. A single-sided film spacer sheet 326A is mounted to an upper, e.g., second, surface 304U of single-sided film spacer singulation tape 304. In one embodiment, single-sided film spacer sheet 326A is in the shape of a wafer allowing use of standard die singulation and pick-and-place processes.

Single-sided film spacer sheet 326A includes a lower film adhesive sheet 332 and a film sheet 330. Single-sided film spacer sheet 326A is singulated, e.g., with a saw 350, thus forming a plurality of single-sided film spacers 126. Each single-sided film spacer 126 includes the respective singulated portion of lower film adhesive sheet 332 and film sheet 330.

FIG. 3B is a perspective view of an assembly 300B during the fabrication of a plurality of single-sided film spacers 126 in accordance with another embodiment of the present invention. Referring now to FIG. 3B, assembly 300B includes a single-sided film spacer roll 326B. Single-sided film spacer roll 326B includes a lower film adhesive sheet 332B and a film sheet 330B. Single-sided film spacer roll 326B is singulated, e.g., with a guillotine 360, thus forming a plurality of single-sided film spacers 126. Each single-sided film spacer 126 includes the respective singulated portion of lower film adhesive sheet 332B and film sheet 330B.

FIG. 4 is a cross-sectional view of stacked electronic component package 100 of FIG. 1 during fabrication in accordance with one embodiment of the present invention. Referring now to FIG. 4, lower electronic component 114 is die attached with adhesive 116 to substrate 102. Bond pads 120 are electrically connected to upper traces 104 with lower bond wires 122.

A vacuum head 402 of a pickup tool 404, sometimes called a pick-and-place tool, grabs upper surface 130U of film 130 of single-sided film spacer 126 in a pick-and-place operation, sometimes called a spacer attach process. As is well-known to those of skill in the art, vacuum is applied to vacuum head 402 suctioning upper surface 130U of film 130 of single-sided film spacer 126 thus causing vacuum head 402 to grab single-sided film spacer 126.

Illustratively, single-sided film spacer 126 is removed from single-sided film spacer singulation tape 304 (FIG. 3A) or from single-sided film spacer roll 326B after single-sided film spacer 126 is singulated (FIG. 3B) by vacuum head 402.

Single-sided film spacer 126 is placed on upper surface 114U of lower electronic component 114 inward of bond pads 120 by vacuum head 402. In one embodiment, single-sided film spacer 126 is pressed downward on to upper surface 114U of lower electronic component 114 by vacuum head 402 to ensure good adhesion between lower film adhesive 132 of single-sided film spacer 126 and upper surface 114U of lower electronic component 114.

After being adhered to upper surface 114U of lower electronic component 114, single-sided film spacer 126 is released from vacuum head 402, i.e., vacuum head 402 of pickup tool 404 is retracted from single-sided film spacer 126. Illustratively, vacuum to vacuum head 402 is discontinued thus discontinuing the suction on single-sided film spacer 126 by vacuum head 402.

As discussed above, upper surface 130U of film 130 of single-sided film spacer 126 is not adhesive. Accordingly, single-sided film spacer 126 does not stick to vacuum head 402 during retraction of vacuum head 402 from single-sided film spacer 126. Thus, voiding between single-sided film spacer 126 and lower electronic component 114 and the associated loss of yield of fabrication of stacked electronic component package 100 is minimized. Further, single-sided film spacer 126 is relatively inexpensive compared to a silicon spacer and thus stacked electronic component package 100 is fabricated with a minimal cost.

Referring again to FIG. 1, to complete fabrication of stacked electronic component package 100, upper film adhesive 128 is applied to lower surface 124L of upper electronic component 124. Upper electronic component 124 including upper film adhesive 128 are pressed into single-sided film spacer 126 thus mounting upper electronic component 124 to single-sided film spacer 126.

Bond pads 136 are electrically connected to respective lower traces 104 by upper bond wires 138. Lower electronic component 114, single-sided film spacer 126, upper film adhesive 128, upper electronic component 124, lower bond wires 122, upper bond wires 138, and all or part of the exposed upper surface 102U of substrate 102 are enclosed in liquid encapsulant or mold compound using any one of the number of encapsulation/molding techniques to form package body 140. Interconnection balls 112, e.g., solder balls, are formed on pads 110 thus completing fabrication of stacked electronic component package 100 although interconnection balls 112 are formed at earlier stages during the manufacturing process in other embodiments.

FIG. 5 is a cross-sectional view of a stacked electronic component package 500 in accordance with another embodiment of the present invention. Stacked electronic component package 500 of FIG. 5 is substantially similar to stacked electronic component package 100 of FIG. 1 and only the significant differences between stacked electronic component package 500 and stacked electronic component package 100 are discussed below.

Referring now to FIG. 5, in accordance with this embodiment, an upper electronic component 124A is larger than lower electronic component 114. Accordingly, upper electronic component 124A overhangs sides 114S of lower electronic component 114. Stated another way, lower surface 124L of upper electronic component 124A is larger than upper surface 114U of lower electronic component 114 such that the total surface area of lower surface 124L is greater than the total surface area of upper surface 114U.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

1. A stacked electronic component package comprising:
a first electronic component having a first surface and a second surface comprising a plurality of bond pads;
a single-sided film spacer coupled to the second surface of the first electronic component inward of the bond pads, the single-sided film spacer comprising:
a non-adhesive organic film; and
a spacer film adhesive; and
a second electronic component having a first surface coupled to the single-sided film spacer by a second electronic component film adhesive, wherein the second electronic component film adhesive is applied to the entire first surface of the second electronic component.

2. (canceled)

3. The stacked electronic component package of claim 1 wherein the second electronic component comprises a second surface comprising bond pads.

4. The stacked electronic component package of claim 3 wherein a substrate comprises first traces on a first surface of the substrate, the stacked electronic component package further comprising:
lower bond wires coupling the bond pads of the first electronic component to respective ones of the first traces; and
upper bond wires coupling the bond pads of the second electronic component to respective ones of the first traces.

5. The stacked electronic component package of claim 4 wherein the second electronic component film adhesive prevents the lower bond wires from directly contacting the first surface of the second electronic component.

6. The stacked electronic component package of claim 5 wherein the second electronic component film adhesive is a dielectric.

7. The stacked electronic component package of claim 6 wherein the lower bond wires contact the second electronic component film adhesive.

8. The stacked electronic component package of claim 1 wherein the second electronic component film adhesive is vertically between the bond pads of the first electronic component and the first surface of the second electronic component.

9. The stacked electronic component package of claim 1 wherein a package body is vertically between the bond pads of the first electronic component and the second electronic component film adhesive.

10. The stacked electronic component package of claim 1 wherein the second electronic component is larger than the first electronic component.

11. The stacked electronic component package of claim 1 wherein the spacer film adhesive comprises more than one film adhesive.

12. The stacked electronic component package of claim 11 wherein a substrate comprises first traces on a first surface of the substrate, the bond pads of the first electronic component being coupled to the first traces with first bond wires, the single-sided film spacer spacing the second electronic component film adhesive above the first bond wires.

13. The stacked electronic component package of claim 11 wherein a substrate comprises first traces on a first surface of the substrate, the bond pads of the first electronic component being coupled to the first traces with first bond wires, the single-sided film spacer providing a sufficient spacing between the second surface of the first electronic component and the second electronic component film adhesive to prevent shorting of the first bond wires.

14-27. (canceled)

28. The stacked electronic component package of claim 1 wherein the spacer film adhesive is a preformed film of adhesive and wherein the second electronic component film adhesive is a preformed film of adhesive.

29. A stacked electronic component package comprising:
a first electronic component comprising:
a first surface;
a second surface; and
bond pads on the second surface;
a substrate comprising:
a first surface;
first traces on the first surface of the substrate;
a second surface; and
second traces on the second surface of the substrate, the first traces being coupled to the second traces;
means for connecting the stacked electronic component package to a larger substrate on the second traces;
first bond wires coupling the bond pads to respective ones of the first traces;
a single-sided film spacer comprising:
a non-adhesive film comprising a non-adhesive surface; and
a spacer film adhesive coupled to the second surface of the first electronic component inward of the bond pads and to the non-adhesive film, the spacer film adhesive comprising:
a first lower film adhesive; and
a second lower film adhesive;
a second electronic component comprising:
a first surface;
a second surface;
bond pads on the second surface of the second electronic component;
a second electronic component film adhesive coupling the first surface of the second electronic component to the non-adhesive surface of the non-adhesive film, the second electronic component film adhesive being located vertically between the bond pads of the first electronic component and the first surface of the second electronic component, wherein the second electronic component film adhesive is applied to the entire first surface of the second electronic component;
second bond wires coupling the bond pads on the second surface of the second electronic component to respective ones of the first traces; and
a package body enclosing the first electronic component, the single-sided film spacer, the second electronic component film adhesive, the second electronic component, the first bond wires, the second bond wires, and at least a portion of the first surface of the substrate.

30. A stacked electronic component package comprising:
a first electronic component comprising:
a first surface;
a second surface; and
bond pads on the second surface;
a substrate comprising:
a first surface; and
first traces on the first surface of the substrate;
first bond wires coupling the bond pads to respective ones of the first traces;
a single-sided film spacer coupled to the second surface of the first electronic component inward of the bond pads, the single-sided film spacer comprising:
a non-adhesive film; and
a spacer film adhesive comprising:
a first means for spacing; and
a second means for spacing;
a second electronic component comprising:
a first surface;
a second surface;
bond pads on the second surface of the second electronic component;
a second electronic component film adhesive coupling the first surface of the second electronic component to the non-adhesive film, the second electronic component film adhesive being located vertically between the bond pads of the first electronic component and the first surface of the second electronic component, wherein the second electronic component film adhesive is applied to the entire first surface of the second electronic component; and
second bond wires coupling the bond pads on the second surface of the second electronic component to respective ones of the first traces.

31. The stacked electronic component package of claim 30 wherein the bond pads on the second surface of the first electronic component comprise a first bond pad and a second bond pad, the first bond pad being inward of the second bond pad.

32. The stacked electronic component package of claim 31 wherein a first bond wire of the first bond wires is coupled to the first bond pad and a second bond wire of the first bond wires is coupled to the second bond pad.

33. The stacked electronic component package of claim 32 wherein the first means for spacing and the second means for spacing define a distance between the second electronic film adhesive and the second surface of the first electronic component.

34. The stacked electronic component package of claim 33 wherein the distance is sufficient to prevent the first bond wire from being pushed down into the second bond wire.

35. The stacked electronic component package of claim 30 wherein the first means for spacing is coupled to the second surface of the first electronic component and the second means for spacing is coupled to the non-adhesive film.
